(19) United States
(12) Patent Application Publication
(10) Pub. No.: US 2010/0123488 A1
(43) Pub. Date: May 20, 2010

(54) DIGITAL PLL WITH KNOWN NOISE SOURCE AND KNOWN LOOP BANDWIDTH

(75) Inventors: Wyn Terence PALMER, Greensboro, NC (US); Kenny GENTILE, Oak Ridge, NC (US)

Correspondence Address: KENYON & KENYON LLP, 1500 K STREET, NW, WASHINGTON, DC, 20005-1257, US

(73) Assignee: ANALOG DEVICES, INC., Norwood, MA (US)

(21) Appl. No.: 12/554,407

(22) Filed: Sep. 4, 2009

Related U.S. Application Data
(63) Continuation of application No. 12/371,262, filed on Feb. 13, 2009.
(60) Provisional application No. 61/114,697, filed on Nov. 14, 2008.
(60) Provisional application No. 61/114,676, filed on Nov. 14, 2008.

(51) Int. Cl. H03K 21/00; H03B 19/00

(52) U.S. Cl. 327/115; 327/116

(57) ABSTRACT

A phase locked loop (PLL) based frequency translator provides a divider augmented with a sigma delta modulator (SDM) in a reference path. The PLL is configured as an all digital PLL and includes a bang-bang phase frequency detector, digital loop filter, and digitally-controlled oscillator. The frequency translator is located in either the reference clock path for division or the PLL feedback loop path for multiplication. The SDM produces a predictable noise characteristic set with known stochastic properties which can be used to smooth any discontinuity in the bang-bang phase frequency detector. The predictable noise of the SDM will produce a dithering delay that eliminates any hard discontinuities. This allows for a bang-bang phase frequency detector based digital PLL.

### CROSS-REFERENCE TO RELATED APPLICATION

This application is a continuation of and claims priority to U.S. patent application Ser. No. 12/371,262, filed on Feb. 13, 2009, the entire contents of each of which are expressly incorporated herein by reference.

### BACKGROUND

Frequency translation circuits, whether for division or multiplication, often include a phase-locked loop (PLL) module. The PLL may include a phase frequency detector (PFD) and an adjustable clock source. The PFD may take the reference signal and compare it to the adjustable clock signal to create an adjustment signal. Solutions currently exist for providing a digital PLL for frequency translation, but these solutions are power and area intensive. One example includes a traditional PFD with an analog-to-digital converter (ADC) and/or analog loop filter. Bang-Bang PFDs (BBPFD) are also known in the art, but create a “hard” discontinuity in the output. BBPFDs therefore, have been primarily used in serializer-deserializer (SERDES) receiver applications where the presence of large amounts of noise on the input signal may be used to smooth the phase discontinuity.

Accordingly, there is a need in the art for a low-power, low-area digital frequency translator and, in particular, a translator that can perform a wide range of conversion ratios.

### BRIEF DESCRIPTION OF THE DRAWINGS

FIG. 1 is a block diagram of a frequency translator according to an embodiment of the present invention.

FIG. 2 is a block diagram of a frequency translator according to another embodiment of the present invention.

FIG. 3 is a PFD decision graph according to a further embodiment of the present invention.

FIG. 4 is another PFD decision graph according to another embodiment of the present invention.

### DETAILED DESCRIPTION

Example embodiments of the present invention illustrate a digital PLL design using a BBPFD and digital loop filter, which allows for a smaller area design and smaller power consumption. To overcome any “hard” discontinuity of the BBPFD, the digital PLL is coupled with a sigma-delta modulator (SDM) controlled variable divider. The SDM may provide fractional frequency division/multiplication ratios and may introduce a noise source with known stochastic properties to smooth the discontinuity of the BBPFD. In this way a digital PLL may be constructed without the drawbacks of prior solutions, e.g., the large area requirement and the heavy power consumption of an ADC-based design.

Embodiments of the present invention provide a digital PLL-based frequency translator in which integer division or multiplication is augmented with a sigma delta modulator (SDM) in a reference path. The combination of an integer divider and an SDM yields a fractional divider that divides by N+F/M, where N is the integer portion of the division and F/M is the fractional portion of the division, with M denoting the fractional modulus. The system may include a Bang-Bang PFD (BBPFD) which is a digital PFD, and the BBPFD may be included in the digital PLL. The PLL may also include a digital loop filter and a digitally controlled crystal oscillator (DCXO). The BBPFD may receive the transformed frequency signal (e.g., the divider output) and the DCXO output (e.g., the PLL output). The BBPFD may then make a binary judgment regarding the phase alignment of the two input waves, and provide an adjusting signal to the DCXO. The PLL has a bandwidth that is the measure of the ability to track the input clock and the jitter (e.g., noise). The closed-loop gain frequency of the PLL determines the PLL bandwidth. When used in conjunction with the BBPFD, the SDM provides a predictable noise characteristic, which may be used to determine the bandwidth of the PLL.

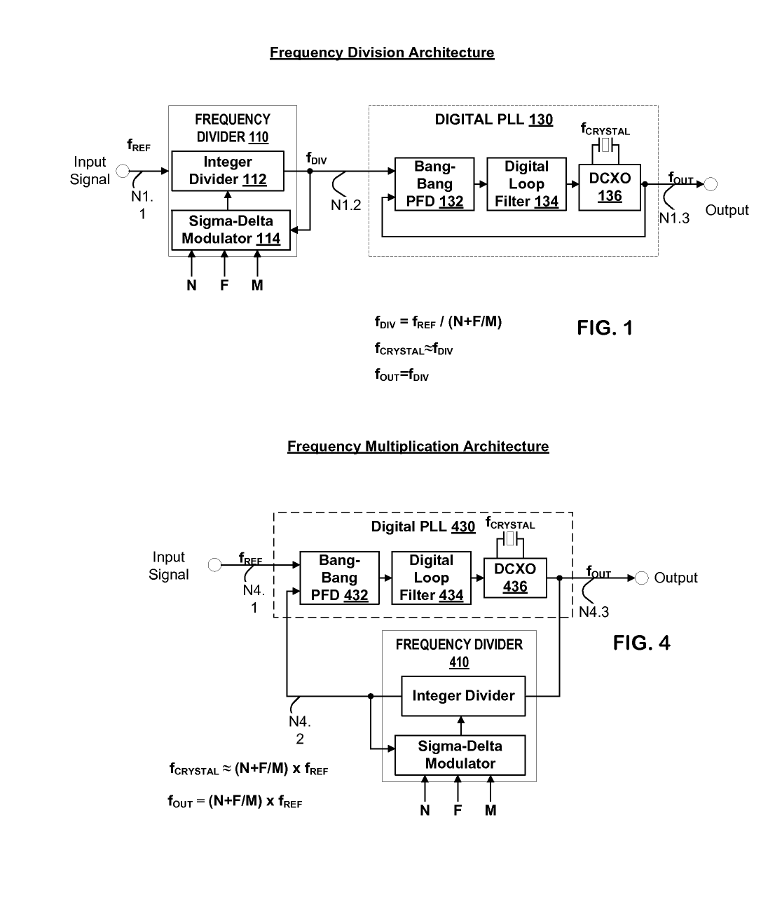

FIG. 1 illustrates a block diagram of a frequency divider 100 according to an embodiment of the present invention. As shown, an input clock signal having frequency f_{REF} may be divided down to an intermediate clock signal having frequency f_{DIV}, via integer divider 112 and sigma-delta modulator 114. The intermediate clock signal f_{DIV} may be input to the BBPFD 132. An output clock having frequency f_{OUT} may be fed back as the second input to the BBPFD 132. The BBPFD 132 may compare the phase difference between the two input signals and may output a control signal representing the phase difference. The control signal may be input to a digital loop filter 134. The loop filter 134 may adjust the DCXO frequency according to filtered phase comparison from the loop filter 134.

During operation, the average frequency of the intermediate clock signal f_{DIV} is equal to the reference frequency f_{REF} divided by the divide ratio applied by divider 112, which is controlled by sigma-delta modulator 114. An example of the divide ratio function is (N+F/M) where N is the integer portion of the divide, and F/M is the fractional portion. Although the frequency divider 110 can achieve non-integer division ratios on average, the instantaneous division ratios may not satisfy the N+F/M division ratio. Thus, the SDM 114 may output continuously variable configuration changes to the integer divider 112 that cause the integer divider 112 to change its instantaneous division ratios. Doing so adds a predictable noise characteristic to the edges introduced in the intermediate clock signal.

During operation, the BBPFD 132 may generate output signals representing phase differences observed in the clock signals input at nodes N1.2 and N1.3. Due to the continuously variable reconfiguration of the frequency divider 110, clock edges in the intermediate clock signal (node N1.2) will not appear at precise, regular intervals. Instead, they will appear at generally regular intervals but with a pseudo-random offset. In the presence of this dither, the effective BBPFD gain may depend on the integrated root mean square (RMS) phase noise of the dither. Phase decisions from the BBPFD 132 also may include a dither effect that, when filtered by the loop filter 134, slow the response of the PLL 130. Additionally, the PLL bandwidth will be very low compared to the SDM modulation rate, resulting in a SDM jitter that is heavily attenuated, even with a low order SDM and loop filter.

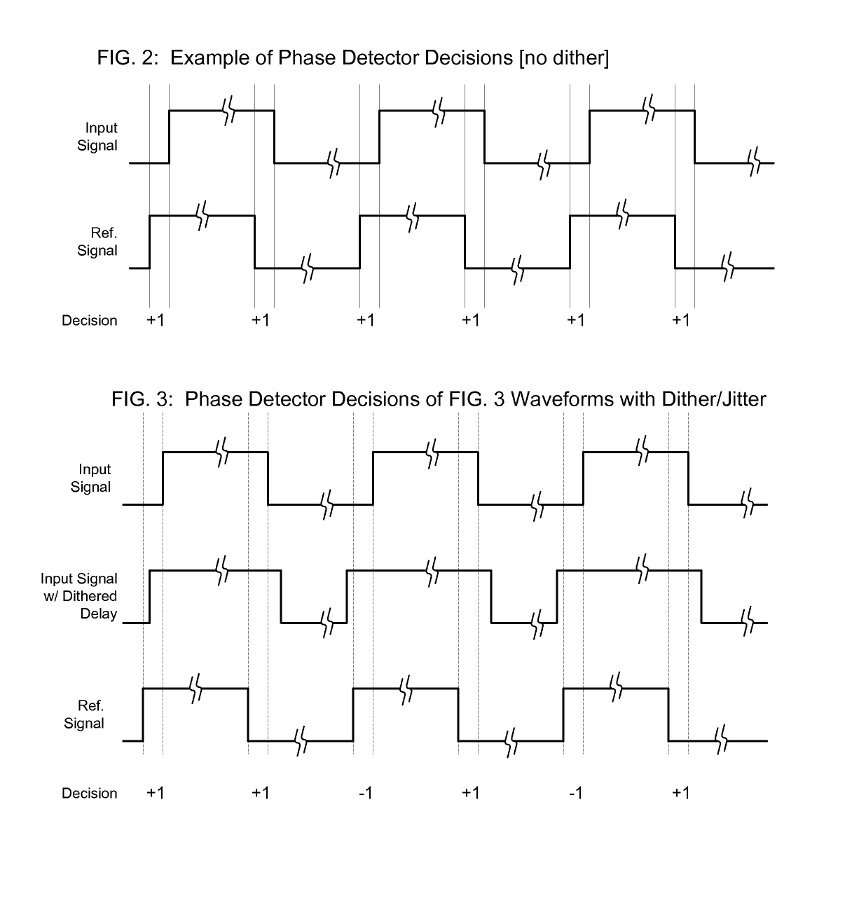

An example illustration of the operation and effective benefit of applying the dithering jitter from the SDM is found in FIG. 3, as compared to FIG. 2, which is an example illustration of operation without a dithering jitter. FIG. 2 illustrates a persistent discontinuity, where the reference signal leads the input signal some unit of time that is essentially fixed in length and constant across the waveforms (e.g., evident at each wave edge). The BBPFD is a binary circuit that compares the edge of one waveform to the edge of another waveform and outputs a signal indicating if the reference signal leads or follows the input signal. As seen in FIG. 2, just as the discontinuity remains present, the same output signal from the BBPFD remains present (e.g., +1 to indicate the reference signal leads the input signal). The BBPFD does not measure the magnitude of the discontinuity, only the binary orientation of the discontinuity. Here, the discontinuity produces a constant “lead” signal of +1. For example, this may be a high signal on a binary circuit or may be defined as the low signal on the same or different binary circuit. Any digital-state device could be implemented in an example embodiment of the present invention.

FIG. 3 shows one example illustration of an example embodiment using a dithered delay, e.g., by incorporating and accounting for a known noise signal. This known jitter may be incorporated into the input signal causing a random delay with known stochastic properties. The resulting decisions of FIG. 3 are no longer uniform. The first rising edge of the reference signal and the first falling edge may lead the dithered input signal and produce a “+1.” However, the second rising edge and third rising edge follow the input signal and produce a “−1.” These are illustrative representations. The actual BBPFD may be a single bit control output where high voltage indicates “+1” and low voltage indicates “−1.” When the difference in signal is smaller than the ability of the BBPFD to measure a difference, the BBPFD may output a “+1” or “−1” according to some rule, logic, or mere random occurrence of either. These potential “errors” are not relevant as they are rendered insignificant compared to the number of measured offsets, and over time will statistically average out. By knowing the stochastic properties of the jitter introduced by the SDM it may be used to improve results of the transformed signal. Each clock edge may have a random and unpredictable delay on the input signal, but in aggregate, after enough calculations have been made, an expected value may be achieved.

FIG. 4 represents another example embodiment of the present invention. In this Figure, the frequency divider 410 is located in the feedback path of the digital PLL 430, and thus is configured as a frequency multiplier. In FIG. 4, the frequency divider 410 receives the DCXO 436 output as the reference clock signal. The BBPFD then compares the divided output of 410 with the reference clock signal N4.1. The divided output N4.2 is a function of the integer divider, controlled by the Sigma-Delta Modulator. The SDM may continuously vary the configuration of the integer divider, which introduces the dithering jitter. For example, each SDM controlled configuration of the integer divider may produce a signal N4.2 that is some small degree off from the desired output frequency (e.g., N4.3 ) of N4.1 times (N+F/M), but taken over a large quantity of clock cycles, may average out to the desired output frequency. Knowing the stochastic properties of this jitter may produced a dithered output at the desired frequency and avoid any persistent discontinuity in the BBPFD. the operation of the BBPFD-based PLL will be smoothed out by the SDM produced dither effect.

Use of the BBPFD inside the PLL enables a pure digital PLL to be designed without the large power consumption associated with prior art designs. In these designs, there is no need for a time-to-digital converter, nor any other analog-to-digital converters. A type-2 digital loop filter may be used, e.g., a loop filter including both a proportional calculation and an integral calculation. The crystal frequency of the DCXO may produce an analog signal, but this signal can be modeled as a digital block to create a pure digital PLL. The DCXO crystal resonator may be an electro-mechanical device that exhibits mechanical inertia, which is essentially the equivalent of electrical latency. This may be modeled as a single pole analog filter of bandwidth Fosc divided by Q, and placed in the control path of the oscillator model. The DCXO crystal resonator is an electro-mechanical device which exhibits mechanical inertia—the equivalent of electrical latency. This is modeled as a single pole analog filter of bandwidth F_{osc}/Q placed in the control path of the oscillator model.

Several embodiments of the present invention are specifically illustrated and described herein. However, it will be appreciated that modifications and variations of the present invention are covered by the above teachings and within the purview of the appended claims without departing from the spirit and intended scope of the invention.

We claim:

1. A frequency translator to perform frequency conversion on a reference clock signal, comprising:
a variable frequency divider having an input for an input clock signal and an output for a divided clock signal, a division ratio of the frequency divider being continuously variable and, therefore, introducing predictable noise characteristics to edges of the divided clock signal;
a digital phase-locked loop (PLL) having an output for an output clock signal, the PLL comprising:
a binary phase-frequency detector (PFD) having inputs for the divided clock signal and for a comparison clock signal,
a digital loop filter having an input coupled to an output of the PFD, and
a digital controlled crystal oscillator (DCXO) having an input coupled to an output of the digital loop filter and an output for the output clock signal.

2. The frequency translator of claim 1, wherein the binary PFD is a Bang-Bang PFD.

3. The frequency translator of claim 1, wherein the input clock signal of the variable frequency divider is connected to the reference clock signal, and the comparison clock signal input is connected to the output clock signal.

4. The frequency translator of claim 1, wherein the input clock signal of the variable frequency divider is connected to the output clock signal, and the comparison clock signal input is connected to the reference clock signal.

5. The frequency translator of claim 1, wherein the variable frequency divider includes a divide ratio input.

6. The frequency translator of claim 5, wherein the divide ratio input is connected to an output of a sigma delta modulator.

7. The frequency translator of claim 6, wherein the sigma delta modulator includes inputs for control parameters N_{A}, F_{A}, M_{A}, wherein the sigma delta modulator is configured to cause the variable frequency divider to perform a frequency conversion according to the ratio:
$$f = \frac{{f}_{IN}}{{N}_{A} + \frac{{F}_{A}}{{M}_{A}}} ,$$
wherein
f_{IN}, is the frequency of the input clock signal.

8. The frequency translator of claim 1, wherein the digital loop filter is a type-2 filter including both a proportional calculation and an integral calculation.

9. A frequency divider to perform frequency conversion on an input clock signal, comprising:
a variable frequency divider having an input for an input clock signal and an output for a divided clock signal, a division ratio of the frequency divider being continuously variable and, therefore, introducing predictable noise characteristics to edges of the divided clock signal;
a digital phase-locked loop (PLL) having an output for an output clock signal, the PLL comprising:
a binary phase-frequency detector (PFD) having inputs for the divided clock signal and for the output clock signal,
a digital loop filter having an input coupled to an output of the PFD, and
a digital controlled crystal oscillator (DCXO) having an input coupled to an output of the digital loop filter and an output for the output clock signal.

10. A frequency multiplier to perform frequency conversion on an input clock signal, comprising:
a digital phase-locked loop (PLL) having an output for an output clock signal, the PLL comprising:
a binary phase-frequency detector (PFD) having inputs for a divided clock signal and the input clock signal,
a digital loop filter having an input coupled to an output of the PFD, and
a digital controlled crystal oscillator (DCXO) having an input coupled to an output of the digital loop filter and an output for the output clock signal; and
a variable frequency divider having an input coupled to the DCXO output and an output for the divided clock signal, a division ratio of the frequency divider being continuously variable and, therefore, introducing predictable noise characteristics to edges of the divided clock signal.

11. A frequency translator to perform frequency conversion on an input clock signal, comprising:
a digital phase-locked loop (PLL) having an output for an output clock signal, the PLL comprising:
a binary phase-frequency detector (PFD) having inputs coupled respectively to a first signal path for an input reference clock signal and to a second signal path for the output clock signal,
a digital loop filter having an input coupled to an output of the PFD, and
a digital controlled crystal oscillator (DCXO) having an input coupled to an output of the digital loop filter and an output for the output clock signal;
a variable frequency divider provided in one of the first and second signal paths, a division ratio of the frequency divider being continuously variable and, therefore, introducing predictable noise characteristics to edges of a clock signal provided in the respective signal path.

12. The frequency translator of claim 11, wherein the variable frequency divider includes a divide ratio input.

13. The frequency translator of claim 12, wherein the divide ratio input is connected to an output of a sigma delta modulator.

14. The frequency translator of claim 13, wherein the sigma delta modulator includes three control inputs: N, F, and M.

15. The frequency translator of claim 14, wherein the variable frequency divider is configured to modify the input clock signal by a factor of N+F/M.
